(19) United States
(12) Patent Application Publication
(10) Pub. No.: US 2013/0285594 A1
(43) Pub. Date: Oct. 31, 2013

(54) ELECTRONIC DEVICE AND CHARGING METHOD

(71) Applicants: HONG FU JIN PRECISION INDUSTRY (SHENZHEN, Shenzhen (CN); HON HAI PRECISION INDUSTRY CO., LTD., New Taipei (TW)

(72) Inventor: XIAO-ZHAN PENG, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 13/675,129

(22) Filed: Nov. 13, 2012

(30) Foreign Application Priority Data
Apr. 28, 2012 (CN) 201210128907.7

(51) Int. Cl. H02J 7/00; H01L 31/052

(52) U.S. Cl. CPC H02J 7/0052; H01L 31/052
USPC 320/101; 136/246

(57) ABSTRACT

An electronic device includes a main body, a solar panel rotatably coupled to the main body, a driving mechanism for rotating the solar panel to different orientations, a detecting unit for detecting intensities of the sunlight received in different orientations, and a processor. The processor compares the detected intensities to determine a greatest intensity, and controls the driving mechanism to rotate the solar panel to an optimal orientation for a short period of time. A charging method implemented by the electronic device is also provided.

### BACKGROUND

1. Technical Field

The present disclosure relates to electronic devices, and more particularly to a charging method implemented by electronic devices.

2. Description of Related Art

The use of alternative energy or power sources, such as solar energy, is growing. A solar panel may be mounted on the shell of an electronic device, such as notebook computer, for converting solar energy to electric energy or to energized the electronic device while simultaneously charging a rechargeable battery of the electronic device. However, the intensity of the received sunlight is changeable when the electronic device moves or the angle of the sun changes, and the solar panel must be manually adjusted to a desired orientation relative to the sun to keep the intensity of the received light as strong as possible, which is inconvenient.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the four views.

FIG. 1 is a perspective view of an electronic device in accordance with an embodiment.

FIG. 2 is a block diagram of the electronic device of FIG. 1; the electronic device includes a rechargeable battery and a solar panel.

FIG. 3 is a perspective view showing the solar panel electrically connected to the rechargeable battery of FIG. 2.

FIG. 4 shows a flow chart of a charging method in accordance with an embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

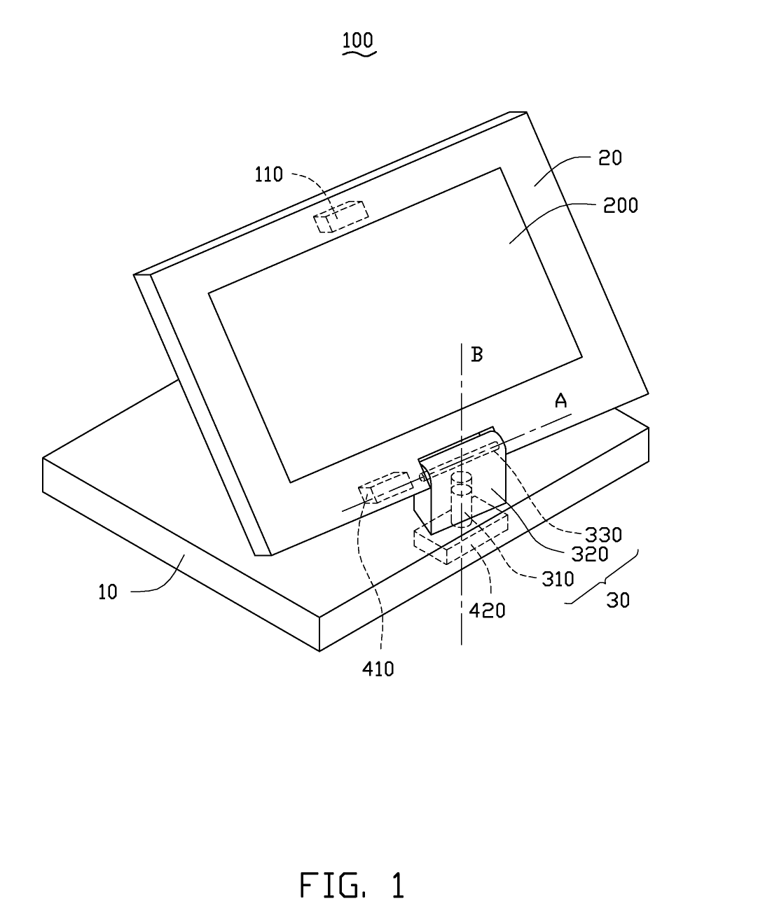

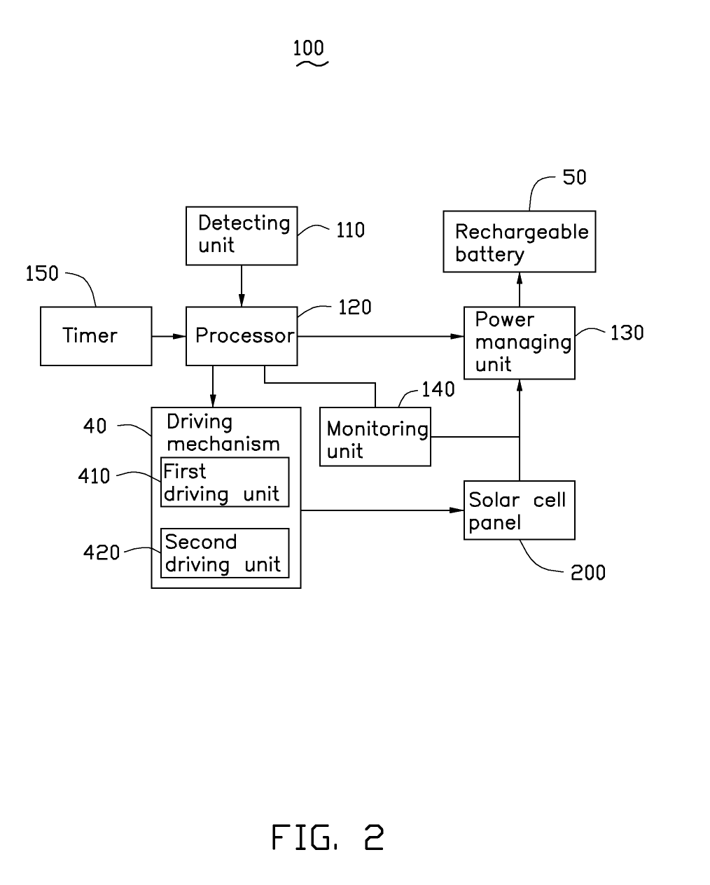

Referring to FIG. 1, an electronic device 100 in accordance with an embodiment is shown. The electronic device 100 in the embodiment is a notebook computer with a solar panel 200. The electronic device 100 includes a main body 10, a cover 20 rotatably coupled to the main body 10, a hinge mechanism 30 connecting the cover 20 to the main body 10, a driving mechanism 40, and a rechargeable battery 50 (see FIG. 2). The driving mechanism 40 drives the cover 20 to rotate relative to the main body 10. The rechargeable battery 50 supplies power for the electronic device 100 when the electronic device 100 is disconnected from an external power source.

The main body 10 is substantially rectangular. The main body 10 receives the rechargeable battery 50, mother board (not shown), HDD (not shown), and other electronic components of the electronic device 100. The size of the cover 20 is substantially equal to that of the main body 10. In the embodiment, a display (not shown) is mounted on a surface of the cover 20. The solar panel 200 is mounted on the surface of the cover 20 which is opposite to the display.

The hinge mechanism 30 includes a fixing portion 310, a pivoting portion 320 rotatably coupled to the fixing portion 310, and a shaft 330 secured to an end of the pivoting portion 320 away from the main body 10. The shaft 330 has an axis A parallel to the main body 10. The shaft 330 is rotatably coupled to the cover 20 for allowing the cover 20 to rotate about the axis A relative to the main body 10. The pivoting portion 320 is rotatably coupled to the fixing portion 310 and is capable of rotating about an axis B perpendicular to the main body 10. The cover 20 being coupled to the shaft 330 also allows the cover 20 to rotate about the axis B relative to the main body 10.

The driving mechanism 40 includes a first driving unit 410 and a second driving unit 420. The first driving unit 410 is secured to the cover 20 and is adapted to rotate the cover 20 about the axis A relative to the main body 10. The second driving unit 420 is secured to the main body 10 and is adapted to rotate the cover 20 about the axis B relative to the main body 10. The first and second driving units 410, 420 are servo motors, or step motors, or a combination. The first driving unit 410 and the second driving unit 420 cooperatively rotate the cover 20 relative to the main body 10, to adjust the orientation of the solar panel 200, whereby the solar panel 200 can constantly receive optimal sunlight.

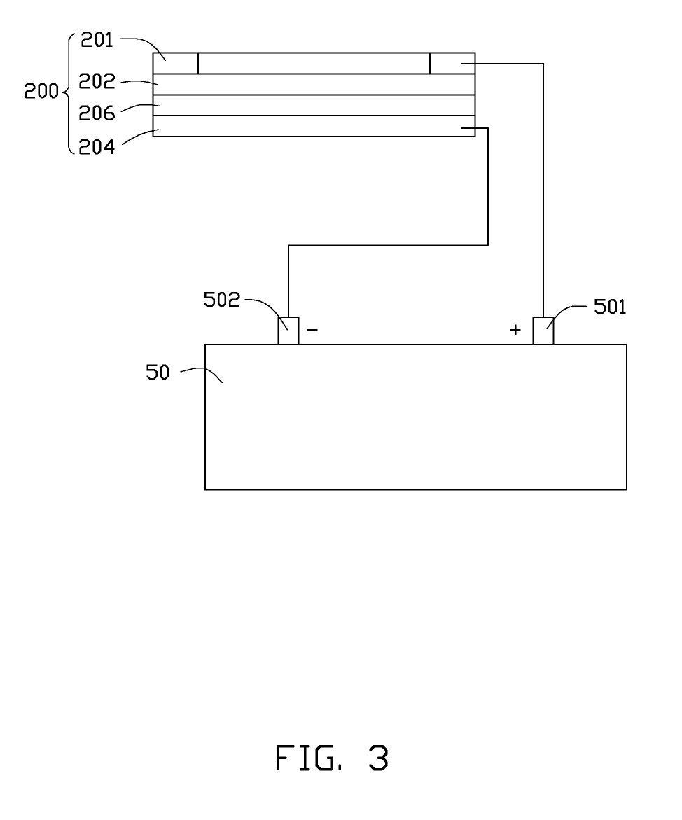

The solar panel 200 is secured to the cover 20, and converts solar energy into electrical energy. Referring to FIG. 3, the solar panel 200 includes a front electrode 201, a transparent conductive layer 202, a back electrode 204, and a photovoltaic semiconductor layer 206 arranged between the transparent layer 202 and the rear electrode 204. Sunlight strikes the transparent conductive layer 202 through the front electrode 201. When the transparent conductive layer 202 is struck by sunlight, the photovoltaic semiconductor layer 206 generates a voltage between the front electrode 201 and the back electrode 204, and photovoltaic conversion is realized.

The rechargeable battery 50 has a positive electrode 501 and a negative electrode 502. When the front electrode 201 is electrically connected to the positive electrode 501, and the back electrode 204 is electrically connected to the negative electrode 502, the rechargeable battery 50 is recharged by the solar panel 200.

Referring to FIG. 2 again, the electronic device 100 further includes a detecting unit 110, a processer 120, a power managing unit 130, a monitoring unit 140, and a timer 150. The detecting unit 110 is adapted to detect the intensity of the sunlight received by the solar panel 200 and transmit the detected intensities to the processor 120. The detecting unit 110 is secured to the cover 20 and is coplanar with the solar panel 200. The detecting unit 110 in the embodiment is a phototransistor.

The monitoring unit 140 is adapted to monitor the voltage generated by the solar panel 200, and generates a signal when the voltage outputted from the solar panel 200 is greater than a predetermined value (such as 0.5 V).

The processor 120 controls the first and second driving units 410 and 420 to rotate the cover 20, such that the solar panel 200 has different orientations. The processor 120 further compares the detected intensities of sunlight to determine an orientation where the intensity is greatest, and generates a signal (a hold signal) for controlling the first and second driving units 410 and 420 to hold the cover 20 stationary in that orientation for a period of time. The processor 120 also controls the power managing unit 130 to charge the rechargeable batter 50 when the signal from the monitoring unit 140 is received.

The timer 150 is electrically connected to the processor 120. The timer 150 begins to time in response to receiving a hold signal, and generates a reset signal after a predetermined time interval, such as 3 minutes. The processor 120 controls the first and second driving units 410 and 420 to rotate the cover 20 again in response to the reset signal, such that the solar panel 200 is again adjusted to search for the strongest sunlight through different orientations. The detecting unit 110 detects intensities, and the processor 120 compares the detected intensities and determines an appropriate orientation where the intensity of the sunlight received by the solar panel 200 is detected to have a greater or the greatest intensity. As a result, through these necessary changes in orientation, the solar panel 200 remains in the optimal orientation, where the intensity of the received sunlight is always the greatest.

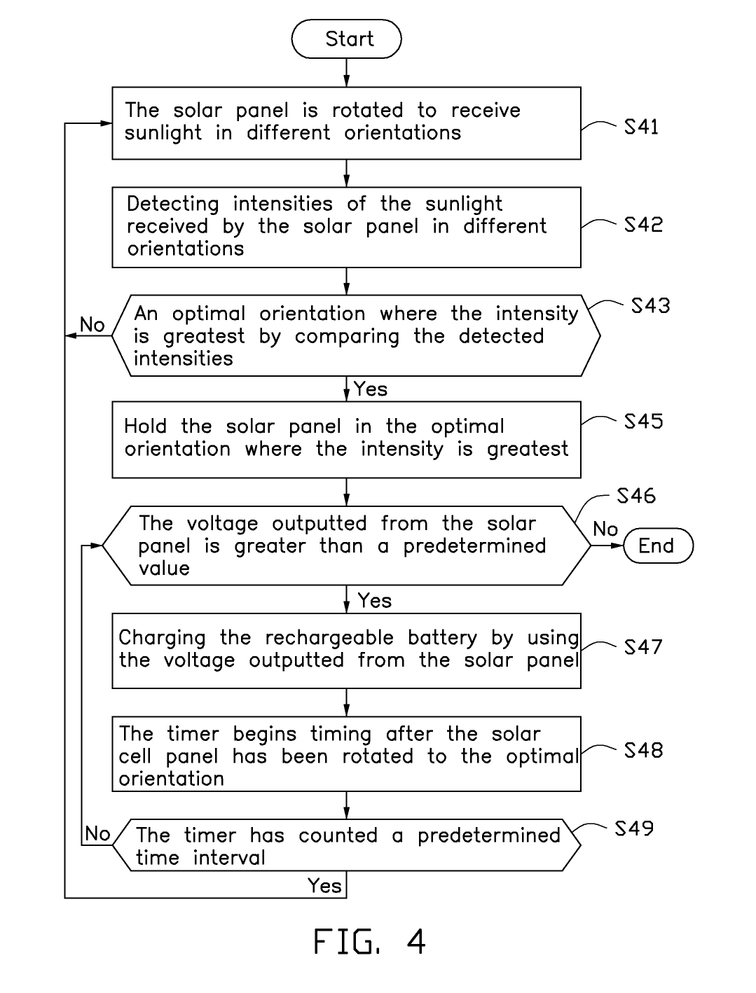

Referring to FIG. 4, a charging method is provided. The charging method may be applied in the electronic device 100 for charging the rechargeable battery 50 by the voltage outputted from the solar panel 200. The electronic device 100 includes a main body 10 and a cover 20 rotatably coupled to the main body 10. The solar panel 200 is secured to the cover 20. The method includes the following steps:

In step S41, the solar panel 200 is oriented to receive sunlight in different orientations.

In step S42, the detecting unit 110 detects intensities of the sunlight received by the solar panel in the different orientations.

In step S43, the processor 120 compares the detected intensities to determine an orientation where the intensity is greatest. If a greatest intensity is determined, the procedure goes to step S45; if not, the procedure returns to step S41.

In step S45, the processor 120 controls the first and second driving units 410 and 420 to hold the solar panel 200 in a particular orientation where the intensity of the received sunlight is deemed to be the greatest.

In step S46, the monitoring unit 140 monitors whether the voltage outputted from the solar panel 200 is greater than a predetermined value, such as 0.5V in the embodiment. If the voltage outputted from the solar panel 200 is greater than a predetermined value, the procedure goes to step S47; if not, the procedure ends.

In step S47, the power managing unit 130 charges the rechargeable battery 50 by using the voltage outputted from the solar panel 200.

In step S48, the timer 150 begins timing after the solar panel 200 has been rotated to an optimal orientation.

In step S49, after the timer 150 has counted a predetermined time interval, such as 3 minutes, the procedure returns to step S41; and if the time timed by the timer 150 does not reach the predetermined time interval, the procedure returns to S46.

It is to be understood, even though information and advantages of the present embodiments have been set forth in the foregoing description, together with details of the structures and functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
a main body;
a solar panel rotatably coupled to the main body, the solar panel for receiving sunlight to convert solar energy to electrical energy;
a driving mechanism for rotating the solar panel to be in different orientations;
a detecting unit for detecting intensities of the sunlight received by the solar panel in different orientations; and
a processor for comparing the detected intensities to determine a particular orientation where the intensity is greatest and further controlling the driving mechanism to rotate the solar panel to the particular orientation.

2. The electronic device of claim 1, further comprising a rechargeable battery and a power managing unit; wherein the power managing unit charges the rechargeable battery by using the voltage outputted from the solar panel.

3. The electronic device of claim 2, further comprising a monitoring unit for monitoring whether the voltage outputted from the solar panel is greater than a predetermined value; wherein the power managing unit charges the rechargeable battery if the voltage outputted from the solar panel is greater than the predetermined value.

4. The electronic device of claim 1, further comprising a cover and a hinge mechanism for rotatably connecting the cover to the main body; wherein the solar panel is mounted on the cover.

5. The electronic device of claim 4, wherein the hinge mechanism comprises a fixing portion secured to the main body, a pivoting portion, and a shaft secured to the pivoting portion and having an axis A, the shaft is rotatably coupled to the cover for allowing the cover to rotate about the axis A relative to the main body; the pivoting portion is rotatably coupled to the fixing portion for allowing the cover to rotate about the axis B relative to the main body; the axis B is perpendicular to the axis A.

6. The electronic device of claim 5, wherein the driving mechanism comprises a first driving unit and a second driving unit; the first driving unit is secured to the cover and is adapted to rotate the cover about the axis A; the second driving unit is secured to the main body and is adapted to rotate the cover about the axis B.

7. The electronic device of claim 1, further comprising a timer; wherein the timer begins to time after the solar panel is rotated to the particular orientation and further determines whether the timer reaches a predetermined time interval; the processor controls the driving mechanism to rotate the solar panel to be in different orientations when the timer reaches a predetermined time interval.

8. The electronic device of claim 7, wherein the detecting unit detects the intensities of the sunlight received by the solar panel in different orientation, and the processor compares the detected intensities to determine an optimal orientation and controls the driving mechanism to rotate the solar panel to the optimal orientation, where the intensity of the received sunlight is always the greatest.

9. A charging method implemented by an electronic device, the electronic device comprising a main body, a solar panel rotatably coupled to the main body and for converting solar energy to electrical energy, and a rechargeable battery, the charging method comprising:
detecting intensities of the sunlight received by the solar panel in different orientations;
comparing the detected intensities to determine a particular orientation where the intensity is greatest;
rotating the solar panel to the particular orientation where the intensity is greatest; and
charging the rechargeable battery by using the voltage outputted from the solar panel.

10. The charging method claim 9, further comprising:
monitoring whether the voltage outputted from the solar panel is greater than a predetermined value; and
charging the rechargeable battery when the voltage outputted from the solar panel is greater than the predetermined value.

11. The charging method of claim 9, further comprising:
beginning to time after the solar panel is rotated to the particular orientation;
determining whether the timer reaches a predetermined time interval; and
rotating the solar panel to a better orientation if the timer reaches a predetermined time interval.

12. The charging method of claim 11, further comprising:
detecting the intensities of the sunlight received by the solar panel in different orientations;
comparing the detected intensities to determine an optimal orientation; and
rotating the solar panel to be in the optimal orientation, where the intensity of the received sunlight is the greatest.
